(19) United States
(12) Patent Application Publication
(10) Pub. No.: US 2025/0202276 A1
(43) Pub. Date: Jun. 19, 2025

(54) SYSTEMS, METHODS, AND STORAGE MEDIA FOR ESTIMATING ELECTROMAGNETIC MOMENTUM IN POWER GRIDS AND ASSESSING NETWORK DYNAMICS AND STABILITY

(71) Applicant: The Regents of the University of Colorado, a body corporate, Denver, CO (US)

(72) Inventors: Amirhossein SAJADI, San Diego, CA (US); Bri-Mathias HODGE, Golden, CO (US)

(21) Appl. No.: 18/980,624

(22) Filed: Dec. 13, 2024

Related U.S. Application Data
(60) Provisional application No. 63/609,734, filed on Dec. 13, 2023.

(51) Int. Cl. H02J 13/00; G01R 31/42; H02J 3/00

(52) U.S. Cl. CPC H02J 13/00002; G01R 31/42; H02J 3/0012

(57) ABSTRACT

A power grid monitoring system includes one or more processors and a memory including instructions. The instructions, when executed by the one or more processors, cause the power grid monitoring system to monitor output measurements from a plurality of power generators and transmission lines connecting the plurality of power generators and loads, estimate an inertial momentum of the plurality of power generators, and predict an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

### CROSS-REFERENCE TO RELATED APPLICATIONS

This application claims the benefit of and priority to U.S. Provisional Patent Application Ser. No. 63/609,734 filed on Dec. 13, 2023, and entitled “METHODS FOR MEASUREMENT AND ESTIMATION OF INTERTIAL MOMENTUM IN ELECTRIC POWER GRID,” which is expressly incorporated herein by reference in its entirety.

### FIELD

The present disclosure relates generally to systems, methods, and storage media for monitoring electric power grids, and more particularly to systems, methods, and storage media for modeling and managing dynamic responses in a power grid network system, which includes high-inertia power grids and low-inertia power grids, which incorporate inverter-based resources.

### BACKGROUND

Electric power grids historically relied on synchronous machines, such as large-scale generators, which inherently provided system inertia that stabilizes frequency fluctuations. However, with the transition toward renewable energy sources, such as solar and wind, and the increased adoption of inverter-based resources, the traditional sources of inertia are rapidly diminishing. This reduction in system inertia leads to increased vulnerability to disturbances, such as sudden changes in load or generation, resulting in frequency instabilities that challenge grid resilience and reliability.

Existing models for analyzing and managing grid dynamics are primarily designed for high-inertia systems and fail to accurately capture the fast dynamics introduced by inverter-based resources. These models often rely on aggregated approximations that do not reflect the true behavior of low-inertia power systems, particularly under transient conditions. Efforts to address this issue have included adaptive control systems and hardware modifications, but these approaches lack a scalable and robust framework for accurately simulating and mitigating the complex interactions between inverter-based resources (IBRs) and the grid.

The lack of accurate and scalable models for low-inertia power systems presents significant challenges to the stability and operational efficiency of modem grids. Specifically, there is a need for a novel dynamic modeling framework capable of representing the spatial and temporal propagation of disturbances in power networks dominated by IBRs.

The subject matter claimed herein is not limited to embodiments that solve any disadvantages or that operate only in environments such as those described above. Rather, this background is only provided to illustrate one exemplary technology area where some aspects described herein may be practiced.

### BRIEF SUMMARY

The present disclosure is related to a grid monitoring system, a method, and a nontransitory medium for modeling and managing dynamic responses in a power grid network system, which includes high-inertia power grids and low-inertia power grids, which incorporate inverter-based resources. The lack of accurate and scalable models for low-inertia power grids presents significant challenges to the stability and operational efficiency of modern grids that could result in blackouts. Specifically, there is a need for a dynamic modeling framework capable of representing the spatial and temporal propagation of disturbances in power networks dominated by low-inertial power generators. This framework may address the limitations of existing models by incorporating real-time measurement and estimation of physical quantity of momenta across the power grid network system, which is quantified using inertia constant in terms of the number of seconds it takes for system frequency to deviate, henceforth simply referred to as “inertial momentum”. Additionally, it provides electric utilities and power grid operators with actionable insights to maintain system stability and security in the presence of rapidly fluctuating renewable energy sources. This disclosure seeks to overcome these challenges by introducing a plane wave dynamic model tailored for high- and low-inertia power systems.

Generally, most conventional power grids operate with high quantities of inertial momentum, provided by synchronous power resources with large momentum of mechanical nature. The low-inertia power grids occur where large concentration of inverter-based resources is present with small momentum of electric nature. As a result, following a disturbance, the low-inertia power grids may experience severe transient behavior due to the small quantities of inertial momentum present. Thus, by controlling the behaviors of the power grid network system according to the amount of inertial momentum present in each region, system performance can be improved and blackouts can be prevented.

According to various aspects of the present disclosure, a power grid monitoring system includes one or more processors and a memory including instructions. The instructions, when executed by the one or more processors, cause the power grid monitoring system to monitor output measurements from a plurality of power generators and transmission lines connecting the plurality of power generators and loads, estimate an inertial momentum of the plurality of power generators, and predict an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

According to various aspects of the present disclosure, a method for monitoring a plurality of power generators includes monitoring output measurements from a plurality of power generators, estimating an inertial momentum of the plurality of power generators and transmission lines connecting the plurality of power generators and loads, and predicting an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

According to various aspects of the present disclosure, a nontransitory storage medium includes instructions stored thereon that, when executed by a computer, cause the computer to perform a method for monitoring a plurality of power generators. The method includes monitoring output measurements from a plurality of power generators, estimating an inertial momentum of the plurality of power generators and transmission lines connecting the plurality of power generators and loads, and predicting an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the present disclosure may be realized and obtained by means of the instruments and combinations particularly pointed out in the appended claims. Features of the present disclosure will become more fully apparent from the following description and appended claims, or may be learned by the practice of the present disclosure as set forth hereinafter.

### BRIEF DESCRIPTION OF THE DRAWINGS

In order to describe the manner in which at least some of the advantages and features of the present disclosure may be obtained, a more particular description of aspects of the present disclosure will be rendered by reference to specific aspects thereof which are illustrated in the appended drawings. Understanding that these drawings depict only typical aspects of the present disclosure and are not therefore to be considered to be limiting of its scope, aspects of the present disclosure will be described and explained with additional specificity and detail through the use of the accompanying drawings.

FIG. 1 illustrates a graphical representation of a power grid network system according to various aspects of the present disclosure;

FIG. 2A illustrates a circuit block diagram for a grid-following inverter-based generator according to various aspects of the present disclosure;

FIG. 2B illustrates a circuit block diagram for a grid-forming inverter-based generator according to various aspects of the present disclosure;

FIG. 3A illustrates data plots of electromagnetic momentum in a transmission line according to various aspects of the present disclosure;

FIG. 3B illustrates data plots of eigenvalues in a complex plane according to various aspects of the present disclosure;

FIG. 3C illustrates data plots of electromagnetic momentum in a transmission line according to various aspects of the present disclosure;

FIG. 3D illustrates data plots of a complex plane according to various aspects of the present disclosure;

FIG. 3E illustrates data plots of electromagnetic momentum in a transmission line according to various aspects of the present disclosure;

FIG. 3F illustrates data plots of eigenvalues in a complex plane according to various aspects of the present disclosure;

FIG. 3G illustrates data plots of electromagnetic momentum in a transmission line according to various aspects of the present disclosure;

FIG. 3H illustrates data plots of a complex plane according to various aspects of the present disclosure;

FIG. 4A illustrates graphical representations showing dynamic stability using a plane wave model in a first power network scenario according to various aspects of the present disclosure;

FIG. 4B illustrates graphical representations showing dynamic stability a using plane wave model in a second power network scenario according to various aspects of the present disclosure;

FIG. 4C illustrates graphical representations showing dynamic stability a using plane wave model in a third power network scenario according to various aspects of the present disclosure;

FIG. 4D illustrates graphical representations showing dynamic stability a using plane wave model in a fourth power network scenario according to various aspects of the present disclosure;

FIG. 5A illustrate data plots showing parametric sensitivity of large-signal plane wave stability model to variations in frequency damping capability according to various aspects of present disclosure;

FIG. 5B illustrate data plots showing parametric sensitivity of large-signal plane wave stability model to variations in voltage damping capability according to various aspects of present disclosure;

FIG. 6A illustrates data plots showing parametric sensitivity of large-signal plane wave stability model to supply of sufficient power during transient operation according to various aspects of present disclosure;

FIG. 6B illustrates data plots showing parametric sensitivity of large-signal plane wave stability model to variations in system momenta according to various aspects of present disclosure;

FIG. 6C illustrates data plots showing parametric sensitivity of large-signal plane wave stability model to variations in system inductance value according to various aspects of present disclosure;

FIG. 6D illustrate data plots showing parametric sensitivity of large-signal plane wave stability model to variations in internal voltage during transient operation according to various aspects of present disclosure;

FIG. 6E illustrate data plots showing parametric sensitivity of large-signal plane wave stability model to variations in voltage transient time-constant according to various aspects of present disclosure;

FIG. 6F illustrates data plots showing parametric sensitivity of large-signal plane wave stability model to variations in ratio of inductance to resistor of the network according to various aspects of present disclosure;

FIG. 7A illustrates data plots for assessing power system dynamics with and without electromagnetic momentum in a first power network having first power disturbance according to various aspects of the present disclosure;

FIG. 7B illustrates data plots for assessing power system dynamics with and without electromagnetic momentum in the first power network having second power disturbance according to various aspects of the present disclosure;

FIG. 7C illustrates data plots for assessing power system dynamics with and without electromagnetic momentum in a second power network having first power disturbance according to various aspects of the present disclosure;

FIG. 7D illustrates data plots for assessing power system dynamics with and without electromagnetic momentum in a second power network having second power disturbance according to various aspects of the present disclosure;

FIG. 7E illustrates data plots for assessing the ratio of electromagnetic momentum to overall momenta present in the first power network according to various aspects of the present disclosure;

FIG. 7F illustrates data plots for assessing the ratio of electromagnetic momentum to overall momenta present in the second power network according to various aspects of the present disclosure;

FIG. 8 illustrates a flowchart for managing a power grid dynamic security according to various aspects of the present disclosure; and

FIG. 9 illustrates a block diagram of a computing device according to various aspects of present disclosure.

### DETAILED DESCRIPTION

The present disclosure is related to a managing model for managing a power grid, which includes legacy/synchronous power resources and inverter-based resources (e.g., solar, wind, wave, or any other renewable generators) in various disturbance scenarios. Although electricity is fundamentally a planar electromagnetic wave, surprisingly, the contemporary dynamic models of power networks treat its transverse electric and magnetic components as independent variables. As a result, frequency and voltage stability are treated as independent problems; voltage stability is treated as a static problem and is focused on the conditions of existence of equilibria, subject to electric circuit constraints (the bifurcation problem), whereas frequency stability is founded upon the Newtonian mechanics of synchronous power resources. Additionally, the momentum of the electromagnetic field that transports the energy, despite being significant, has not been considered. Such treatment has held valid for more than half a century since the advent of modern power grids mainly because of the structural properties of conventional power networks, especially synchronous power resources, that allowed for a series of simplifications which result in treating this complex network as an electromechanical network rather than an electromagnetic network. This has obscured a number of contemporary issues in power system dynamics, such as grid strength and forced oscillations until the recent wide-spread adoption of inverter-based renewable resources that break away from the synchronous power resource-based paradigm. These problems may be addressed with the following aspects by considering the treatment of electricity as electromagnetic waves and, subsequently, the presentation of power network dynamics in two dimensions.

Disclosed aspects utilize the electromagnetic momentum stored in the electromagnetic field around the transmission lines in power networks directly from Maxwell's laws of electromagnetism and computer simulations and field data demonstrate the physical significance of this component, whose contributions have thus far been overlooked in the electric power network literature and not utilized in practice. Subsequently, the disclosed model is able to handle dynamics and stability in power systems based on the electromagnetic coupling of voltage and frequency, which fills a number of gaps in current power system dynamics theory. In contrast to the conventional understanding that considers the invariant mechanical inertia of synchronous power resources as the sole contributing component to system inertia, the disclosed models demonstrate that the concept of effective inertia in power networks is time-variant and has contributions dependent both on the network conditions and the generator structural properties.

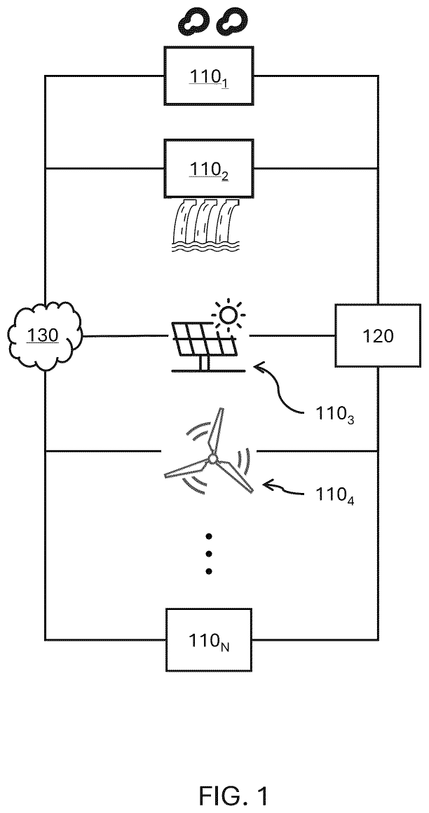

Referring now to FIG. 1, illustrated is a power grid network system 100 according to various aspects. The power grid network system 100 may include various power generators, which are power plants 1101, hydroelectric power plants 110₂, solar power plants 110₃, window power plants 110₄, and other various types of power plants 110_{N}. The power plants 1101 may be powered by nuclear, coal, natural gas, diesel, geothermal, or the likes to rotate one or more turbines, which have generally a heavy weight. On the other hand, the solar power plants 110₃, the wind power plants 110₄, fuel cell, and electrochemical battery storage generate direct current (DC) power either through direction DC generation or conversion to DC for power conditioning. All of them include inverters to convert the DC power to AC power. From now on, any renewable power plants, which include inverters in power generation, are referred to inverter-based power resources (IBRs) in this disclosure.

Power generated by the power plants 110 is transferred to a load 130, which may be factories, residentials, commercials, and any other facilities and buildings, via transmission lines. Based on needs from the load 130, a monitoring system 120 may manage the power plants 110. Further, based on regular load switching in a power network and disruptions in power transfer due to mechanical problems, electrical problems, environmental situations, or any other causes, the monitoring system 120 may control deactivation and reactivation of the power plants 110. During transient stages, the monitoring system 120 may leverages the inertial momentum to manage imminent transient behaviors of the synchronous power plants (e.g., the power plants 1101, the hydroelectric power plants 110₂, or the likes) following any disturbances.

For example, the power plants 1101 rotate one or more turbine to generate alternating current (AC) power. Likewise, the hydroelectric power plants 110₂ use potential power kept in water to rotate turbines to generate AC power. These turbines generally have a physical mass with significant weight. From now on, any power plants, which rotate one or more turbines to generate AC power, are referred to synchronous power resources. Due to rotations of heavy turbines, the synchronous power resources have inherent inertia, which helps stabilize the voltage and the frequency of the AC power. In other words, the mechanical momentum of the heavy turbines prevents sudden changes in the rotation of the turbines, thereby preventing sudden deviations in frequency of the AC power, according to Newtonian First and Second Laws of Motion.

On the other hand, IBRs do not have the mechanical momentum sufficient to guarantee frequency preservation capabilities after power generation disturbances, instead they have electric momentum. The monitoring system 120 may utilize a new model (i.e., the plane wave model) for handling the imminent transient behaviors of the IBRs following any disturbances. Such will be described in detail below.

The IBRs may have two types: one is a grid-following inverter (GFL) and the other one is a grid-forming inverter (GFM). The GFL is a power electronic device used to integrate an IBR into an existing power grid (e.g., the power grid network system 100), operate by synchronizing its output with voltage and frequency of the power grid network system 100 by following the grid's conditions, and rely on the power grid network system 100 to maintain stability and security and do not operate independently of the power grid network system 100 without external support, while the GFM is a power electronic device used to establish and regulate the voltage and frequency of an IBR, independent of external sources. Unlike the GFLs, the GFMs may be able to operate autonomously forming the voltage and frequency of the IBR and making them particularly suitable for microgrids, weak grids, or hybrid grids with high penetration of renewable energy.

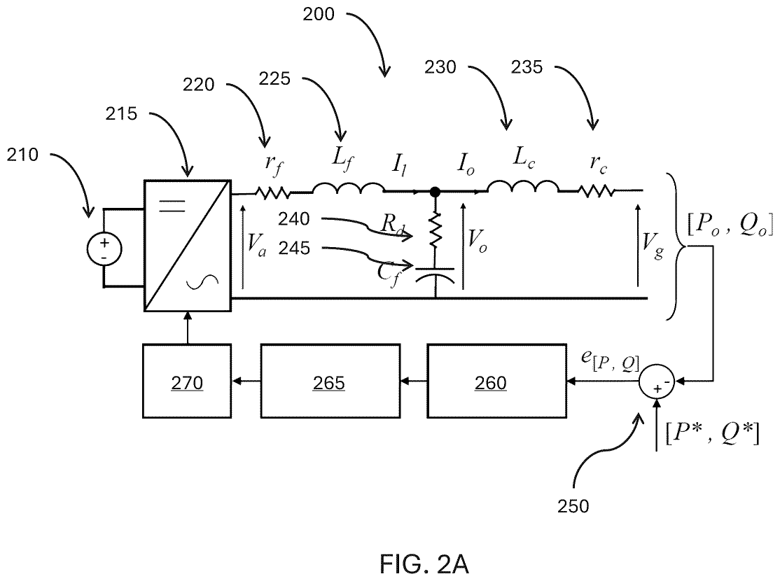

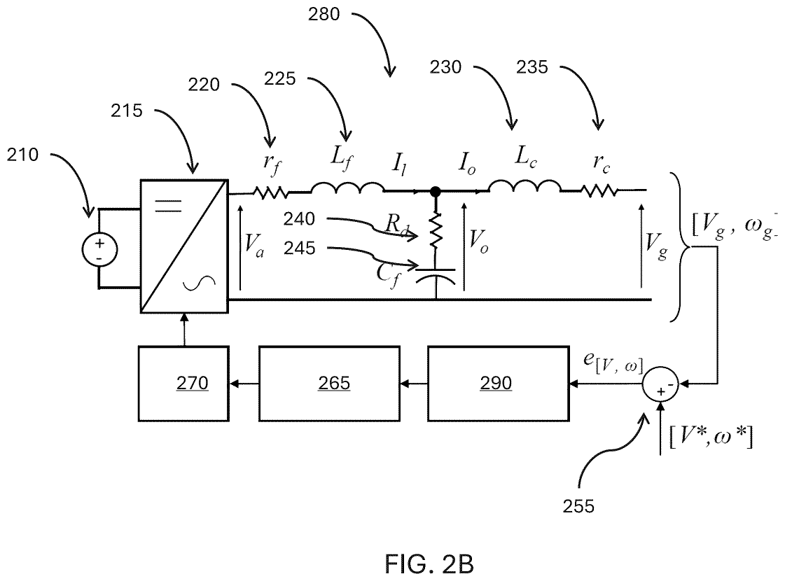

Further details about IBRs including GFLs and GFMs will be described with respect to FIGS. 2A and 2B, respectively. The IBR 200 may include a renewable energy generator 210 (e.g., solar panels, wind power generators, wave power generators, etc.), which generates DC power, and an inverter 215, which converts the DC power into AC power. In an aspect, the renewable energy generator 210 may a battery system, which provides DC power to the inverter 215.

The voltage at the inverter 215 is Vₐ, which is filtered by a filter to dissipate and damp undesired transient energy with high harmonics to ensure smoother output voltage Vₒ and current Iₒ. The filter may include a filter resistor 220 with resistance of r_{f}, a filter inductor 225 with inductance of L_{f}, a damping resistor 240 with resistance of R_{d}, and a capacitor 245 with a capacitance of C_{f}. The voltage at the output of the filter is Vₒ and the current therethrough is Iₒ. The electrical power output from the filter is transferred to the grid via a transmission line, which has a resistance of r_{c} and an inductance of L_{c}. At the grid, the IBR supplies voltage V_{g}, real power Pₒ, and reactive power Qₒ.

The IBR 200 may include a comparator 250, which compares the real power Pₒ and the reactive power Qₒ with a reference real power Pₒ* and a reference reactive power Qₒ*, respectively. The comparator 250 outputs the difference between the real powers and between the reactive powers.

The IBR 200 may further include a power controller 260, which receives the differences and generates a control signal, a current controller 265, which generates a modulated signal, and a PWM generator 270, which generates a PWM signal based on the modulated signal. The PWM signal may drive the inverter 215, which generates proportional AC power compared to the total power capacity of the IBR 200 based on its duty cycle thereof.

Now referring to FIG. 2B, an IBR 280 may include a renewable energy generator 210 (e.g., solar panels, wind power generators, wave power generators, etc.), which generates DC power, and an inverter 215, which converts the DC power into AC power. The IBR 280 may include a GFM. The configuration of the IBR 280 is substantially similar to that of the IBR 200 except a comparator 255 and a power controller 290. Thus, any description for the same components (e.g., the renewable energy generator 210, the inverter, the resistors 220, 240, and 235, the inductors 225 and 230, and the capacitor 245) can be found above in those of FIG. 2A.

The comparator 255 may receive voltage V_{g}, and a phase ω_{g} of the voltage and compare them with a reference voltage V* and a reference phase ω*, respectively. The errors therebetween are outputs from the comparator 255 and inputs to the voltage controller 290, which generates a modulated signal for the current controller 265. In turn, the GFM is controlled by voltage, while the GFL is controlled by current.

Now, power flow in electric power networks may be explained by the Poynting theorem, which is an extension of Maxwell's equations. Maxwell's equations explain that the electromagnetic field, where energy is stored, is composed of both electric and magnetic field vectors, \vec{E} and \vec{H}, respectively, that are inseparable and lie in a plane which is transverse to the axis of energy propagation. The Poynting vector, \vec{S}=\vec{E}×\vec{H}, which is a polarized wave, composed of mutually perpendicular waves differing in time and amplitudes, quantifies the amount of power that leaves the surface in which the energy is stored and is equivalent to the negative of the work done on the charges within the volume minus the losses. The Poynting theorem links Maxwell's laws of electromagnetism to Kirchhoff's laws of circuit theory, which form the basis for the power flow equation used in electric power networks. The Poynting Vector in the integral form is presented as:

$${∮}_{A} \vec{S} \cdot d \vec{A} = - \frac{\partial }{\partial t} ( {\int }_{{V}_{H}} \frac{1}{2} \cdot μ \cdot {\vec{H}}^{2} \cdot {dV}_{H} + {\int }_{{V}_{ε}} \frac{1}{2} \cdot ε \cdot {\vec{E}}^{2} \cdot {dV}_{ε} ) - {\int }_{{V}_{Ω}} \vec{E} \cdot \vec{J} \cdot {dV}_{Ω} , \qquad ( 1 )$$

where A is the cross-sectional surface area through which the electric power is transferred. V_{H} and V_{E} are the volumes of free space around the transmission line where magnetic and electric fields are enclosed, respectively, and V_{Ω} is the volume of the space within the conductor in which resistive losses occur. ε and μ are the electric permittivity and magnetic permeability, respectively, the material characteristics of a conductive medium and define its response to electric and magnetic fields.

Based on Equation (1), the electric power, s= [symbol] _{A}\vec{S}·d\vec{A}, is the rate of change of energy stored in the electromagnetic field, w, with time t,

$$s = \frac{\partial }{\partial t} w ,$$

that is the aggregation of the power that exits in the surface area of the transmission line, and the total power stored in the magnetic and electric fields. In an AC power network, which is a harmonic field, the energy function of the electromagnetic field can be calculated by:

$$ω = - \frac{1}{2} {\int }_{{V}_{H}} ( \frac{\vec{Φ}}{l \cdot d} \cdot \frac{{\vec{ι}}^{*}}{2 \cdot π \cdot {r}_{Φ}} ) \cdot {dV}_{H} - \frac{1}{2} {\int }_{{V}_{ε}} ( \frac{\vec{q}}{2 \cdot π \cdot {r}_{q} \cdot l} \cdot \frac{{\vec{v}}^{*}}{l} ) \cdot {dV}_{ε} - \int {\int }_{{V}_{Ω}} \frac{R}{l \cdot π \cdot {\hat{r}}^{2}} \cdot {\vec{ι}}^{*} \cdot \vec{ι} \cdot {dV}_{Ω} \cdot dt , \qquad ( 2 )$$

where \vec{i} is electric current in the transmission line that connects nodes i and j, and, according to Faraday's law, \vec{Φ}= [symbol] _{A}_{_{Φ}}μ·\vec{H}·dA_{Φ}= [symbol] _{A}_{_{Φ}}\vec{B}·dA_{Φ} is the magnetic flux linkage that passes through the area A_{Φ} of the open space between transmission lines in overhead lines at point i. A_{Φ}=l·d, and \vec{B} is the magnetic flux density. l is the length of the transmission line, d is the distance between adjacent conductors of the transmission line, r_{Φ} is the radius of the magnetic field lines as formed in the free space around the conductor. \vec{v} is voltage at any point along the line and according to Gauss's law,

$$\vec{q} = {\int }_{{A}_{q}} ε \cdot \vec{E} \cdot {dA}_{q} = {\int }_{{A}_{q}} \vec{D} \cdot {dA}_{q} , \qquad ( 3 )$$

where the electric charge within the area A_{q} and \vec{D} is the electric flux density, assuming electric charges are distributed uniformly on the conductor surface along the line, denoted by A_{q}, and ignoring the ground capacitance. The area is described by A_{q}=2·π·r_{q}·l where r_{q} is the radius of the electric field lines as formed in the free space around the conductor. Electric resistance is:

$$R = \frac{ρ l}{π {\hat{r}}^{2}} , \qquad ( 4 )$$

where \hat{r} is the radius of the conductor and ρ is the electric resistivity of the conductor, defined as \vec{E}=ρ·\vec{J}, a material property that measures how strongly it resists electric current. The total electric charges inside the area A_{q} can be expressed as

$$q = {∮}_{{A}_{q}} \vec{D} \cdot {dA}_{q} = C \cdot \vec{v} , \qquad ( 5 )$$

where C is the effective shut capacitance and \vec{v} is voltage. The magnetic fix linkage can be expressed as

$$Φ = {∮}_{{A}_{Φ}} \vec{B} \cdot {dA}_{Φ} = L \cdot \vec{ι} , \qquad ( 6 )$$

where L is the effective series inductance. * is the conjugate operator of complex value or variable.

Replacing the magnetic flux linkage and electric charge values yields:

$$w = - \frac{1}{2} ( L \cdot \vec{i} \cdot {\vec{i}}^{*} + C \cdot \vec{v} \cdot {\vec{v}}^{*} ) - \int R \cdot {\vec{i}}^{*} \cdot \vec{i} \cdot dt . \qquad ( 7 )$$

The is the total energy filled inside a volume V. The power flow equation then can be obtained by simply taking the time derivative of the energy function w as:

$$\frac{\partial w}{\partial t} = - L \cdot {\vec{i}}^{*} \cdot \frac{\partial }{\partial t} \vec{i} - R \cdot {\vec{i}}^{*} \cdot \vec{i} , \qquad ( 8 )$$

where the parasitic capacitance, C, is reasonably ignored. By defining the current in phasor representation as:

$$\vec{i} = {\overline{Y}}_{ij} \cdot ( {V}_{j} \cdot {e}^{j ( {w}_{j} t + {δ}_{j} )} - {V}_{i} \cdot {e}^{j ( {w}_{i} t + {δ}_{i} )} ) , \qquad ( 9 )$$

Where Vᵢ and Vⱼ are the root-mean-square (RMS) voltage amplitudes at the i and j nodes and δᵢ, wᵢ, δⱼ, and wⱼ are the phase angle and frequency of the i^{th} and j^{th} nodes. Y̅ᵢⱼ is the admittance of the line that connects the two nodes in phasor notation. The power flow equation for the i^{th} node, in quasi-steady state, wᵢ≈wⱼ, consists of two terms,

$$\frac{\partial w}{\partial t} = \frac{\partial {w}_{S}}{\partial t} + \frac{\partial {w}_{Ω}}{\partial t}$$

and each term is given as:

$$\frac{\partial {w}_{S}}{\partial t} = {L}_{ij} \cdot {\overline{Y}}_{ij} \cdot {\overline{Y}}_{ij}^{*} \cdot {V}_{i} \cdot ( {V}_{i} \cdot {e}^{j ( {δ}_{i} - {δ}_{j} )} - {V}_{i} ) \cdot \frac{\partial {δ}_{i}}{\partial t} \qquad ( 10 )$$

$$\frac{\partial {w}_{Ω}}{\partial t} = {R}_{ij} \cdot {\overline{Y}}_{ij} \cdot {\overline{Y}}_{ij}^{*} \cdot {V}_{i} \cdot ( {V}_{i} \cdot {e}^{j ( {δ}_{i} - {δ}_{j} )} - {V}_{i} ) .$$

It is commonly represented in phasor form as:

$$\frac{\partial w}{\partial t} = {\overline{Y}}_{ij}^{*} \cdot {V}_{i} \cdot ( {V}_{j} \cdot {e}^{j ( {δ}_{i} - {δ}_{j} )} - {V}_{i} ) , \qquad ( 11 )$$

which is the power flow equation for power systems. The first term

$$\frac{\partial {w}_{S}}{\partial t}$$

means that the power that exits the surface area of the conductor as the delivered power. The second term

$$\frac{\partial {w}_{Ω}}{\partial t}$$

means that the dissipated power in the conductor as the ohmic losses.

The equation (10) describes the propagation of energy across a power network through the electromagnetic field that is formed around the transmission lines and highlights the electric angle, denoted by δᵢ, and the voltage magnitude, denoted by Vᵢ. The electric angle δᵢ is directly linked to the strength of the magnetic field—the value of (δᵢ−δⱼ) determines an amplitude of the magnetic field along the path between i^{th} and j^{th} nodes, and

$$\frac{\partial {δ}_{i}}{\partial t} = {w}_{i}$$

determines the frequency of i^{th} oscillations. The voltage magnitude is also directly linked to the strength of the electric field—the value of Vᵢ determines an amplitude of the electric field at the i^{th} node, and the frequency of its oscillation coincides with that of the magnetic field.

An electromagnetic field around a transmission line, in addition to transferring power, also stores energy (and for that matter also electromagnetic momentum). This electromagnetic momentum stems from the mass equivalent of the energy flow in the electromagnetic field around the transmission line, which is a fundamental property of an electromagnetic field according to the law of conservation of momentum. The amount of power transferred in an electromagnetic field is determined by the amplitudes of electric and magnetic fields, whereas the phase difference between the two components is directly defined by the power factor for AC power systems. The power factor is a ratio of the real part of the Poynting Vector (active power) to its absolute value, which is based on the active power and reactive power, i.e., the imaginary part of the Poynting Vector. The power factor determines the nature of the power transferred-capacitive, inductive, or resistive. In this regard, the line angular momentum, Mₗ, may be estimated or measured based on the following equation:

$${M}_{l} = \int \vec{r} \times ( \frac{1}{{c}^{2}} \cdot \vec{S} ) \cdot dr , \qquad ( 12 )$$

where

$$\frac{1}{{c}^{2}} \cdot \vec{S}$$

is the momentum density that a field carries in vacuum which is the flux density of the mass equivalent of energy flow in the field, c is speed of light, \vec{r} is a unit vector, and the integration is over all space bounding the electromagnetic field for the entire length of the line. The symbols × and · are the cross product and dot product operators. Equation (12) makes it evident that the amount of electromagnetic momentum is directly proportional to the loading level of a line, which determine \vec{S}, and its voltage rating and length which collectively determines the integration space. A change in the flow of power in a power line changes the energy density in its electromagnetic field which is directly proportional to the amplitudes of its constituting waves. Thus, the most prominent impact of the line electromagnetic momentum in an electric power network is experienced by tis electric angles.

It is noted that the electric circuit of a transmission system contains a large number of transformers that are highly magnetic components. On the other hand, their electromagnetic field is locally bounded to the location of their operation, yielding a small volume of enclosed space. Consequently, their independent electromagnetic momentum is relatively small, and because their electromagnetic link is a part of the overall Poynting vector that transfers power between two nodes, their impact is aggregated along the entire transmission lines.

Further, it is noted that the bundled structure of conductors in transmission lines may influence the cross-sectional surface A, and the Poynting vector \vec{S} is the power density, thus when integrated over the enclosed space volume V, it only becomes a function of the net amount of power transferred and the length of the transfer, independent of the cross-sectional surface area. Thus, the line momentum or electromagnetic momentum is independent of the line structural design.

Now, a plane wave dynamic model for power generator networks is described to capture the transient behaviors that may appear following a disturbance along the electromagnetic link established between generators and loads via the interconnecting transmission lines. The power flow equations, shown in Eq. (10), attested to a direct dependence of energy propagation across the power network to the electric angle and voltage magnitude of all the nodes. The plane wave dynamic equations to describe the electric angle and voltage at the i^{th} node of a power network may be:

$${\ddot{δ}}_{i} = {M}_{i}^{- 1} ( {P}_{{g}_{i} -} {D}_{i} \cdot ( {w}_{i} - {w}_{S} ) - {f}_{i} ( δ , V ) ) \qquad ( 13 )$$

$${\dot{V}}_{i} = {T}_{{V}_{i}}^{- 1} ( {E}_{{g}_{i}} - {V}_{i} - {g}_{i} ( δ , V ) ) ,$$

where δᵢ and Vᵢ are the electric angle and the voltage of the i^{th} node of the power network, respectively, Mᵢ=M_{g}_{ᵢ}+Mₗ_{ᵢ} is the total momentum at ith node, which is the summation of the momentum of the generator M_{g}_{ᵢ} connected to the i^{th} node, and the electromagnetic momentum Mₗ_{ᵢ} associated with the transmission lines connected to the i^{th} node. The momentum of the generator M_{g}_{ᵢ} may be a mechanical momentum for a synchronous generator and an electric momentum for an IBR. Thus, the total momentum or the inertial momentum is a sum of mechanical momenta, electric momenta, and electromagnetic momenta. In an aspect, the sum may be a vector sum.

The line or electromagnetic momentum is the aggregate of the momenta values of all j number of transmission lines that are directly connected to the i^{th} node. Thus, Mₗ_{ᵢ}=Σₖ₌₁^{j}Mₗ_{ᵢₖ}, where Mₗ_{ᵢₖ}≠Mₗ_{ₖᵢ} since the electromagnetic momentum is conditioned on the direction of flow of the power. Tᵥ_{ᵢ} is the transient voltage time constant of the i^{th} generator that articulates the number of seconds it takes for its terminal voltage to change. Dᵢ is frequency damping functions that approximate the frequency response/control actions, respectively, and hold distinct values for each generation technology. Equation (13) considers all three power conversion technologies that are in the landscape of the transition to 100% renewable-based power networks, which include synchronous power resources, grid-following inverter-based resources, grid-forming inverter-based resources, virtual synchronous machine (VSM), multi-loop droop GFM (GFM-droop), and virtual oscillator control (VOC) devices.

Each device may be modeled by distinct momentum values M_{g}_{ᵢ} and Tᵥ_{ᵢ} and damping function Dᵢ. Network flow functions are:

$${f}_{i} ( δ , V ) = {V}_{i}^{2} \cdot {Y}_{ii} \cdot cos ( {α}_{ii} ) + {\sum }_{j = 1 \& i \neq j}^{n} {V}_{i} \cdot {V}_{j} \cdot {Y}_{ij} \cdot cos ( {δ}_{i} - {δ}_{j} - {α}_{ij} ) \qquad ( 14 )$$

for real power, and

$${g}_{i} ( δ , V ) = \vert {Z}_{m} \cdot {Y}_{ii} \cdot {e}^{j ( {δ}_{i} + {α}_{ii} )} + {\sum }_{j = 1 \& i \neq j}^{n} {V}_{j} \cdot {Y}_{ij} \cdot {e}^{j ( {δ}_{j} + {α}_{ij} )} \vert \qquad ( 15 )$$

for voltage,
where Y̅ᵢ̅ⱼ̅ is the mutual admittance between nodes i and j, and can be expressed in complex form by Y̅ᵢ̅ⱼ̅=Yᵢⱼ∠αᵢⱼ, and Y̅ₗ̅ₗ̅ is the self-admittance of the i^{th} node. Zₘ is the magnetizing impedance of the i^{th} generator. In synchronous power resources, Zₘ is the armature reaction reactance of magnetizing reactance and, in inverter-based generators, Zₘ is the impedance between the LCL/LC filter input and its capacitor. P_{g}_{ᵢ} is the i^{th} generator's real power that is converted from the primary energy source into AC electric power by the interfacing device (e.g., synchronous machine or inverter). E_{g}_{ᵢ} is the i^{th} generator's excitation voltage. In synchronous power resources, it is the excitation emf and in inverter-based generators equipped with voltage source converters (VSC), it is the AC side of the semiconductor switches that is the input to the LCL/LC filter.

$${w}_{i} = \frac{\partial {δ}_{i}}{\partial t}$$

is the frequency at the i^{th} node and wₛ is the network synchronization frequency. Its fixed points form the necessary condition of power balance in the power network: active power produced should be equal to the power consumed and excitation voltage should be to regulate voltage magnitude within the standard operational range at all times.

The link may be established between nodal frequency and voltage by direct incorporation of differential equations that describe their dynamics at the network-level. This characterization may be consistent with the complex frequency that uses the localized curvature of the frequency-power manifold to establish a direct link between the azimuthal and radial components, with the assumption that the relationship between the frequency changes in any two adjacent nodes in a power network of interest are linear. Modeling dynamics of power networks in two-dimensional space is a departure from the frequency stability convention, which is centered on a swing equation that describes the synchronization dynamics of power networks in a single-dimensional differential equation. The classical swing equation has served as the ground truth for studying various aspects of power system dynamics and synchronization for more than half a century, accompanied by a series of algebraic equations to estimate network-level voltage.

On the other hand, the plane wave dynamic model, as disclosed in this disclosure, presents similarities to the classical swing equation, because it is a more complete form of swing equation. If the traditional assumptions are followed, the equation reduces to the classical the swing equation. That is, in a configuration where the term related to the electromagnetic momentum, Mₗ, is ignored and it is assumed that the reactive power support of the generator is so generous that the availability of required reactive power, and subsequently voltage regulation, is a given, the swing equation can be derived. For example, E_{g}_{ᵢ}=Vᵢ+gᵢ(δ, V) and the dynamic voltage differential terms become algebraic equality terms, this formulation is reduced to M_{g}_{ᵢ}·\ddot{δ}ᵢ=P_{g}_{ᵢ}₋D_{w}_{ᵢ}·(wᵢ−wₛ)−Pₑ, where Pₑ is the electric power that the i^{th} generator exports, and that is the classical swing equation.

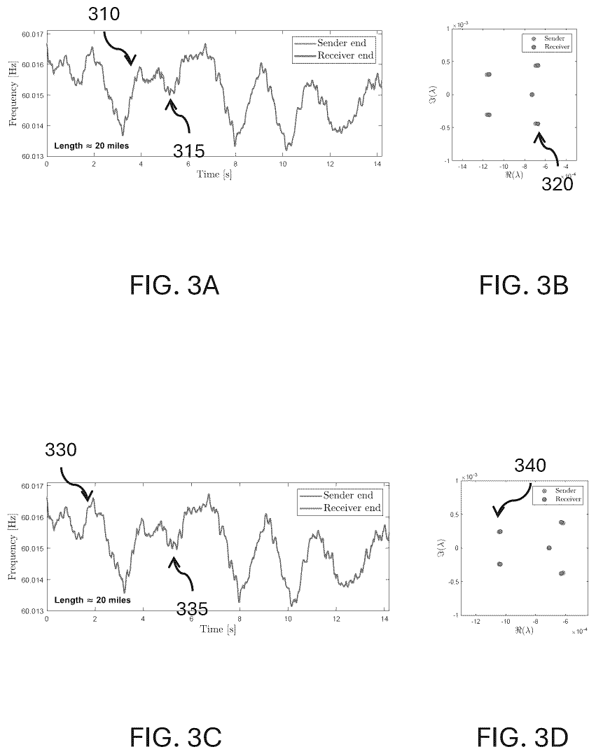

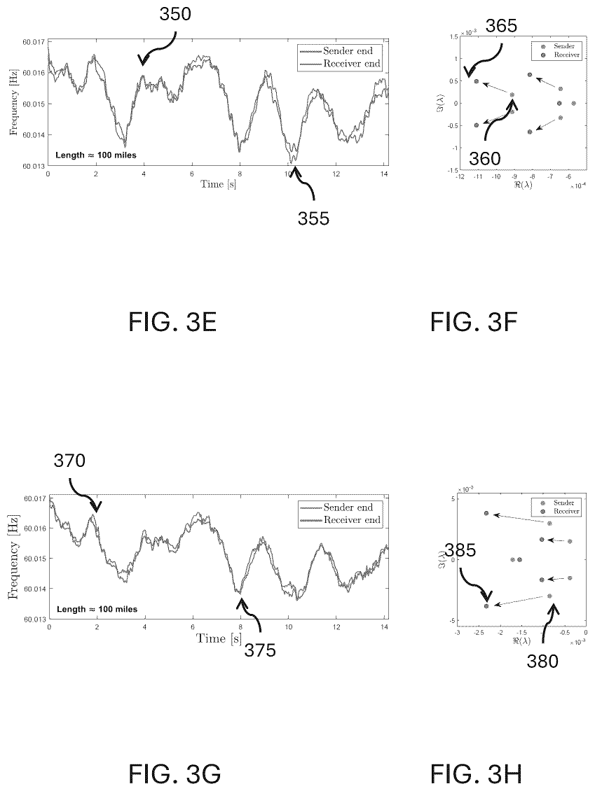

FIGS. 3A, 3C, 3E, and 3G illustrate electromagnetic momenta in a transmission line with different lengths to provide the evidence of their significance in frequency dynamics. In particular, FIGS. 3A and 3C show frequency fluctuations in a 20-mile transmission line along the passage of time, while FIGS. 3E and 3G show frequency fluctuations in a 100-mile transmission line along the passage of time. Likewise, FIGS. 3B, 3D, 3F, and 3H illustrate eigenvalues in a complex plane with different lengths. In particular, 3B and 3D show eigenvalues in complex plane in the 20-mile transmission line, while FIGS. 3F and 3H show changes in eigenvalues in the 100-mile transmission line.

Data plot 310 shows frequency fluctuations at a sender end, meaning the generator or grid side, and data plot 315 shows frequency fluctuations at a receiver end, meaning the load side. The transmission line between the sender end and the receiver end is 20 miles. When the electromagnetic energy is injected into the 20-mile transmission line from the sender end, the frequency fluctuations appear to be substantially the same at the sender end and the receiver end based on the data plot 310 and 315. This illustrates how the electromagnetic momentum in the transmission line acts as a buffer against rapid changes in the transmitted energy and frequency. In fact, the frequency changes at the sender end and at the receiver end are within a range of about 0.004 Hz with respect to 60 Hz of the AC energy.

FIG. 3B shows stable characteristics of the 20-mile transmission line's dynamic behavior at the sender end and the receiver end. The horizontal axis represents real components of the eigenvalues in the unit of 10⁻⁴, and the vertical axis represents imaginary components of the eigenvalues in the unit of 10⁻⁴.

All real eigenvalues 320 are negative, confirming that the system is dynamically stable. A larger negative real component indicates faster decay of disturbances, while a value close to zero indicates slower stabilization. On the other hand, the imaginary components suggests oscillatory behavior. Thus, the larger the absolute value of the imaginary component is, the more violent the oscillatory behavior is, and vice versa.

Since the eigenvalues 320 at the sender end are substantially the same as those at the receiver end, substantially stable characteristics suggest that there are no significant differences in oscillatory behaviors based on the electromagnetic momentum at the sender end and at the receiver end. Further, nearly identical eigenvalues show that the transmission line introduces uniform damping and stability effects.

Data plots 330 and 335 and the eigenvalues 340, as illustrated in FIGS. 3C and 3D, are also obtained from another 20-mile transmission line. Similar to the data plots 310 and 315, the data plots 330 and 335 are substantially similar to each other at the sender end and at the receiver end. Also, similar to the eigenvalues 320, the eigenvalues 340 also show no differences between at the sender and receiver ends.

On the other hand, with the 100-mile long transmission line, data plots 350 at the sender end of FIG. 3E and data plot 355 at the sender end of FIG. 3G illustrate frequency fluctuations different from data plot 355 at the receiver end of FIG. 3E and data plot 370 at the receiver end of FIG. 3G, respectively. Due to the longer length of the transmission line, the electromagnetic momentum becomes larger than that in the 20-mile transmission line. In other words, the volume of the surface bounding the electrical charges in the electromagnetic field along the 100-mile transmission line is relatively larger than the volume of such along the 20-mile transmission line, thereby increasing the electromagnetic momentum, because the electromagnetic momentum is proportional to the volume.

Further, as illustrated in FIG. 3F, the absolute value of the imaginary component of the eigenvalue 360 at the sender end is less than the absolute value of the imaginary component of the eigenvalue 365 at the receiver end. Due to the increase in the absolute value, the oscillatory behavior at the receiver end is relatively larger than that at the sender end. Since the real component of the eigenvalue 360 at the receiver end is smaller than the real component of the eigenvalue 360 at the sender end, a faster decay of the disturbance is expected at the receiver end.

Likewise, as illustrated in FIG. 3H, the absolute value of the imaginary component of the eigenvalue 380 at the sender end is less than the absolute value of the imaginary component of the eigenvalue 385 at the receiver end. Due to the increase in the absolute value, the oscillatory behavior at the receiver end is relatively larger than that at the sender end. Since the real component of the eigenvalue 360 at the receiver end is smaller than the real component of the eigenvalue 380 at the sender end, a faster decay of the disturbance is expected at the receiver end.

Based on FIGS. 3A-3H, eigenvalues reflect dynamic stability and oscillatory behavior of the transmission line system, capturing influence of electromagnetic momentum on energy transfer. The eigenvalues' placement in the complex plane demonstrates the power grid network system's ability to maintain stability and dampen oscillations for modern grid systems with increasing renewable energy resources.

Now, the plane wave dynamic equation for a power system that includes a generator at node g, that supplies a load at node l, through a transformer and transmission line. In this system, the dynamics of frequency \dot{ω}₉ and voltage magnitude \dot{V}_{g} at the generator node may be calculated by:

$$[ \begin{matrix}{\dot{ω}}_{g} \\ {\dot{V}}_{g}\end{matrix} ] = {\underbrace{[ \begin{matrix}\frac{1}{\text{?}} & 0 \\ 0 & \frac{1}{\text{?}}\end{matrix} ]}}_{{ϕ}_{n}} \cdot [ \begin{matrix}{P}_{g} - {P}_{l} \\ {E}_{g} - {E}_{l}\end{matrix} ] - {\underbrace{[ \begin{matrix}\frac{1}{\text{?}} & 0 \\ 0 & \frac{1}{\text{?}}\end{matrix} ]}}_{{ϕ}_{n}} \cdot [ \begin{matrix}{D}_{g} \cdot {\dot{δ}}_{g} \\ \vert {Z}_{m} - {I}_{gl} \vert\end{matrix} ] + {\underbrace{[ \begin{matrix}- \frac{\text{?}}{\text{?}} & 0 \\ 0 & - \frac{\text{?}}{\text{?}}\end{matrix} ]}}_{{k}_{n}} \cdot [ \begin{matrix}{\dot{ω}}_{l} \\ {\dot{V}}_{l}\end{matrix} ] , \qquad ( 17 )$$

$$\text{?} \text{indicates text missing or illegible when filed}$$

where \dot{ω}ₗ and \dot{V}ₗ are the frequency and voltage dynamics at the load node, ωᵢ=\dot{δ}ᵢ, D_{g} is the generator's damping function, P_{g} and E_{g} are the active power and the excitation voltage of the generator, respectively, and Pₗ and Eₗ are the active power consumption at the load node and the voltage delivered the terminals of the body where work is being done, respectively, M_{gl} is the frequency momenta of the generator and transmission line combined, Tᵥ_{_{g}} is the generator's voltage transient time constant, those of the load are Mₗ and Tᵥ_{ₗ}, Zm is the magnetization impedance present in the circuit which is equivalent to that of generator and load combined, \dot{δ}_{g}=ω₉−ωₛ, where wₛ is the synchronization angular frequency, and I_{gl} is the current that flows between the generator and the load.

The equation (17) may describe the generator's transient trajectory following an external disturbance, and suggest that there are three distinct contributing components to its oscillations. The first term is ϕₙ·[P_{g}−PₗE_{g}−Eₗ]^{T} represents the dynamics that are excited by a power and voltage imbalance, e.g., load switch, change of network topology, and are contributed by available generation capacity (headroom reserve) to meet the consumption of load and the magnetization of the network.

The second term is ϕₙ·[D_{g}·\dot{δ}_{g} |Zₘ·I_{gl}|]^{T}, which represents the damping functions or the generator's ability to dissipate the transients and return to an equilibrium. D_{g} serves as the frequency damping function, and Zₘ acts as the voltage damping coefficient.

The third term is kₙ·[\dot{ω}ₗ\dot{V}ₗ]^{T} corresponds to the interactive dynamics that are excited in the adjacent nodes subsequent to the power imbalance or a load-driven disturbance that produces dynamic motions or transient behaviors. The arrays of Φₙ are reciprocal values of the frequency momenta of generator and line combined and the voltage transient time constant of the generator. The arrays of kₙ are negative values of the ratio of the frequency momentum and voltage transient time constant of the load to the power grid network. The negative values imply different direction of oscillations. The third term may be relevant when the system is serving loads with high inertia (e.g., large motors), presenting special case. Thus, in this disclosure, the load dynamics are ignored.

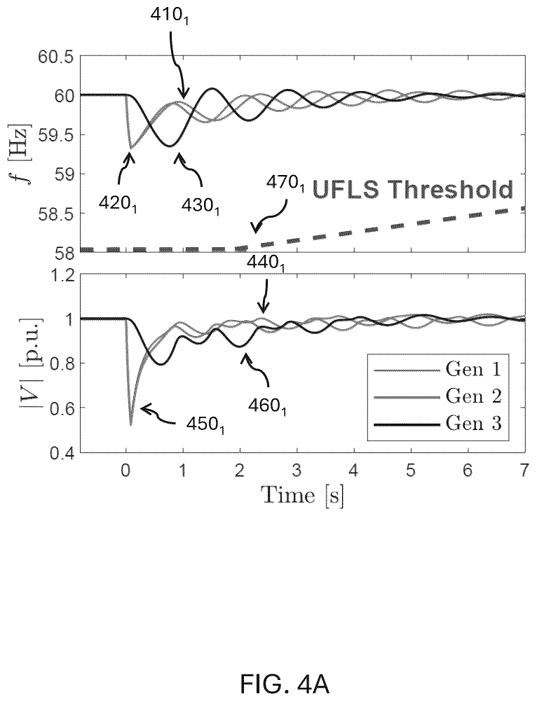

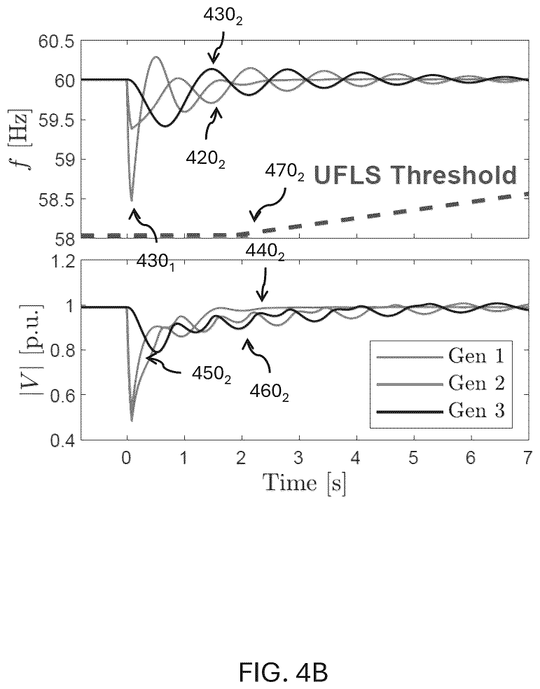

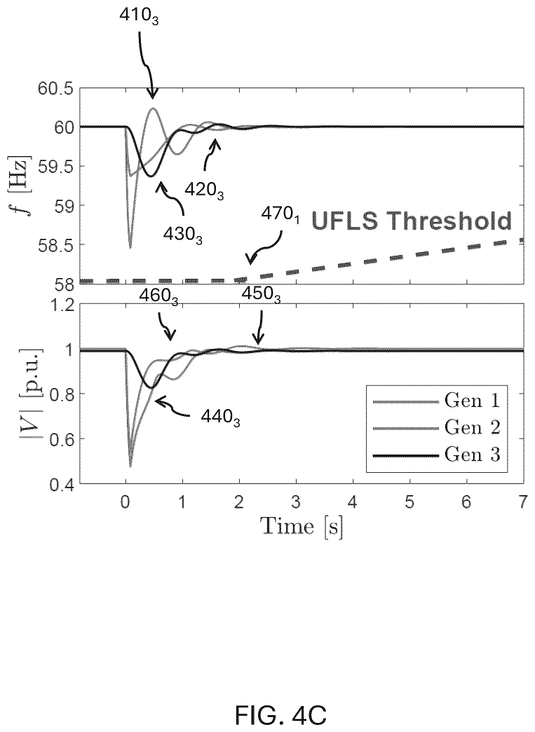

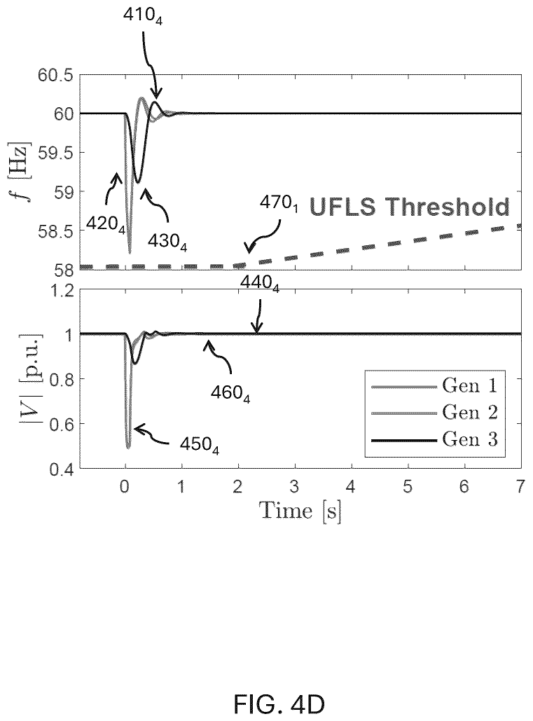

Various situations are considered to see efficacy of the plane wave dynamics of power networks for simultaneous consideration of frequency and voltage dynamics with any mixture of synchronous power resources and IBRs as referring to FIGS. 4A-4D. Specifically, FIG. 4A illustrates data plots 410₁-460₁ with three synchronous power resources, FIG. 4B illustrates data plots 410₂-460₂ with two synchronous power resources and one GFM, FIG. 4C illustrates data plots 410₃-460₃ with one synchronous power resource and two GFMs, and FIG. 4D illustrates data plots 410₄-460₄ with three GFMs without any synchronous power resource. Perturbation is applied in the form of a three-phase symmetrical fault between generators 1 and 2 and sustained for 83 milliseconds, which is equal to 5 electrical cycles in 60 Hz. Remedial action and system restoration to its pre-fault topology follow. Under four situations, the system loading is identical.

The top graph of each of FIGS. 4A-4D shows frequency fluctuations along the passage of time and the bottom graph of each of FIGS. 4A-4D shows voltage fluctuations along the passage of time. After the perturbation is applied to the first and second generators 1 and 2, the frequency and the voltage at the first and second generators 1 and 2 drop according to the data plots 410₁, 420₁, 440₁, and 450₁. In the meanwhile, the frequency and voltage of the third generator 3 also drop, but the amount of changes in the frequency and the voltage of the third generator 3 is relatively smaller than those of the first and second generators 1 and 2 based on the data plots 430₁ and 460₁.

FIGS. 4A-4D also includes an under-frequency load shedding (UFLS) curves 470₁-470₄ are protective mechanisms used in the power grid network systems to prevent the power grid network systems from collapsing when the system frequency drops below a critical threshold due to an imbalance between generation and load. It involves automatically disconnecting (shedding) certain loads to restore balance and stabilize the grid frequency.

Now based on comparisons among the data plots 440₁-460₁ of FIG. 4A, the data plots 440₂-460₂ of FIG. 4B, the data plots 440₃-460₃ of FIG. 4C, and the data plots 440₄-460₄ of FIG. 4D, voltage deviations are similar under all four situations. After the remedial action, the post-fault voltage transient decreases in FIG. 4A because the three synchronous power resources have a small voltage transient time constants. The first situation of three synchronous power resources illustrated in FIG. 4A is one extreme situation of mixture of three generators.

On the other hand, the fourth situation of three IBRs illustrated in FIG. 4D is the other extreme situation of mixture of three generators. After the remedial action, the post-fault voltage transient decreases in FIG. 4D because the three IBRs have a small voltage transient time constants. When compared to the post-fault voltage transient of FIG. 4A, the post-fault voltage transient of FIG. 4D decreases much faster than that in FIG. 4A because the GFM has a much greater damping capability than synchronous power resources. Likewise, frequency dynamics illustrated in the data plots 410₄-430₄ of FIG. 4D are stabilized much faster than the frequency dynamics illustrated in the data plots 410₁-430₁ of FIG. 4A because the inverters have a small inertial momentum but relatively high damping capability, which leads to faster dissipation of oscillations.

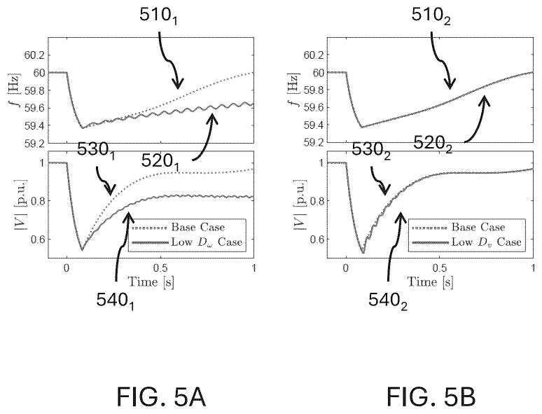

Now referring to FIG. 5A, illustrated are, in response to the reduced frequency damping capability of generator D_{w}, frequency data plots 5101 and 5201 for frequency dynamics and voltage data plots 530₁ and 540₁ for voltage dynamics. The horizontal axis represents the time in unit of seconds, the vertical axis of the top graph is the frequency in Hz, and the vertical axis of the bottom graph is the voltage value relative to a chosen base voltage.

Under this situation, the reduced frequency damping capability of generator D_{w} are forcibly introduced into the power network system during a transient period after perturbation is applied in the form of a three-phase symmetrical fault between generators and sustained for 83 milliseconds. Here, the forcible introduction of the frequency oscillations D_{w} may mimic mechanical, electrical, or environmental errors introduced into the power network system. The duration of the perturbation may be longer or shorter than 83 milliseconds.

Now referring to FIG. 5A, illustrated are, in response to the reduced frequency damping capability of generator D_{w}, frequency data plots 510₁ and 520₁ for frequency dynamics and voltage data plots 530₁ and 540₁ for voltage dynamics. Under this situation, a reduced frequency damping capability of generator D_{w} is forcibly introduced into the power network system during a transient period after perturbation is applied in the form of a three-phase symmetrical fault between generators and sustained for 83 milliseconds. Here, the forcible introduction of a reduced frequency damping capability of generator D_{w} may mimic mechanical, electrical, or environmental errors introduced into the power network system. The duration of the perturbation may be longer or shorter than 83 milliseconds.

The reference frequency data plot 510₁ and the reference voltage data plot 530₁ are provided for references. In other words, the reference frequency data plot 510₁ and the reference voltage data plot 530₁ show the frequency and voltage responses after the perturbation without introduction of the reduced frequency damping capability of generator D_{w}. The voltage data plot 540₁ depicts that the reduced frequency damping capability of generator D_{w} causes oscillations in the voltage, and the frequency data plot 520₁ depicts that a reduced frequency damping capability of generator D_{w} causes oscillations in the frequency. Thus, the reduced frequency damping capability of generator D_{w} can be spread into the frequency and voltage, thereby the frequency data plot 520₁ not following the reference frequency data plot 510₁ and the voltage data plot 540₁ not following the reference voltage data plot 520₁.

Now referring to FIG. 5B, illustrated are, in response to a reduced voltage damping capability of generator Dᵥ, frequency data plots 510₂ and 520₂ for frequency dynamics and voltage data plots 530₂ and 540₂ for voltage dynamics. Under this situation, a reduced voltage damping capability of generator Dᵥ is forcibly introduced into the power network system during a transient period after perturbation is applied in the form of a three-phase symmetrical fault between generators and sustained for 83 milliseconds. Here, the forcible introduction of a reduced voltage damping capability of generator Dᵥ may mimic mechanical, electrical, or environmental errors introduced into the power network system. The duration of the perturbation may be longer or shorter than 83 milliseconds.

The reference frequency data plot 510₂ and the reference voltage data plot 530₂ are provided for references. In other words, the reference frequency data plot 510₂ and the reference voltage data plot 530₂ show the frequency and voltage responses after the perturbation without introduction of a reduced voltage damping capability of generator Dᵥ. The voltage data plot 540₂ depicts that a reduced voltage damping capability of generator Dᵥ do not cause substantial oscillations in the voltage, and the frequency data plot 520₂ depicts that a reduced voltage damping capability of generator Dᵥ do not cause substantial oscillations in the frequency. Thus, a reduced voltage damping capability of generator Dᵥ do not substantially spread into the frequency and voltage, thereby the frequency data plot 520₂ substantially following the reference frequency data plot 510₂ and the voltage data plot 540₂ substantially following the reference voltage data plot 5202.

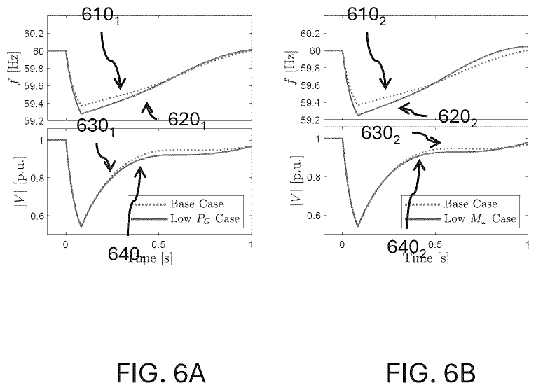

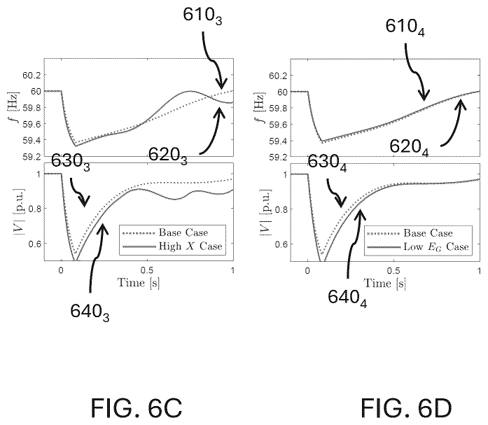

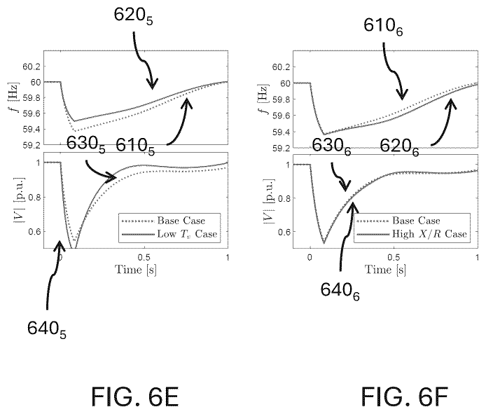

There are many contributing factors related to the strength and the transient stability of a power network system. For example, the first prominent factor is the ability of the power generators to supply sufficient power and maintain a firm internal voltage during transient periods, as illustrated in FIGS. 6A and 6D; the second prominent factor is the generator's dynamic characteristics, as illustrated in FIGS. 6B and 6E; and the third prominent factor is the transmission networks' characteristics, as illustrated in FIGS. 6C and 6F.

The horizontal axis of FIGS. 6A-6F represents the time in unit of seconds. Each of FIGS. 6A-6F includes two graphs. The vertical axis of the top graph represents the frequency in unit of Hz, and the vertical axis of the bottom graph represents the voltage value relative to a chosen base voltage. Numerals 610₁-610₆ represent reference frequency data or base data, numerals 620₁-620₆ represent frequency output data, numerals 630₁-630₆ represent reference voltage data or base data, and numerals 640₁-640₆ represent voltage output data.

Now returning to FIGS. 6A and 6D, the first prominent factor is illustrated in terms of a short circuit ratio (SCR) of generators. The SCR ratio has been utilized and proven practical as a heuristic solution where a higher SCR implies a stronger grid. It has been used as a rule of thumb approach and a practical proxy to estimate the availability of synchronous power resource-like support during extreme transients. A high SCR is practical only if robust electromagnetic properties for the interconnecting transmission line are provided so that it is capable of sustaining the electromagnetic field even during extreme transients. The SCR is more broadly addressed in the context of the active-reactive power (P-Q) capability characteristics of a generator that determines its ability to absorb or inject active and reactive power, whereas the transmission line capability is discussed in the context of the network transfer capability, especially in dealing with thermal stability and voltage stability. The generators (e.g., IBRs) with constrained capability to provide active and reactive power support during an extreme transient event, during an electrical short-circuit since the limiting factor is the use of semiconductor switches, could comprise grid stability and strength. This explains why synchronous condenser technologies have been widely recognized as a solution to the grid strength problem, simply because the high short circuit current capability they offer prevents demagnetization of the line through transient reactive power to support the electromagnetic field, in addition to the inertial support they provide for a smoother frequency response. Reactive power support from a synchronous condenser during a fault and after its clearance also relieves IBRs with GFM control from some of the reactive power (voltage) support, allowing them to provide active power during the fault and preventing a significant frequency drop with more effective frequency damping, which also serves to dampen voltage oscillations.

Now returning to FIGS. 6B and 6E, the second prominent factor is illustrated in terms of the generator's dynamic characteristics, which are the inertial frequency momentum and the voltage transient time constant. While it is evident that the reduced generator inertia and voltage transient time constant will result in more deviations and frequency and voltage transients, it also results in a faster recovery subsequent to the clearance of the external disturbance. Hence, high shares of IBRs could result in larger frequency and voltage deviation during a disturbance. On the other hand, if there are IBR GFM resources present, both frequency and voltage oscillations may be mitigated rapidly because of their enhanced damping capability and low inertia. Mass integration of GFL technology alone can pose stability challenges because of the lack of damping capability, as evidenced by the majority of the instabilities witnessed in the real-world blackouts.

Now returning to FIGS. 6C and 6F, the third prominent factor is illustrated in terms of the transmission network's characteristics. Specifically, FIG. 6C illustrates a high X case, meaning that the power network system is more susceptible to more extreme oscillations so that the data plots 6203 and 6403 are deviated afar from the base data plots 6103 and 6303. There are two root causes for this deviations. First, a damping ratio ζ of oscillations in the system is inversely proportional to the X value. As a result, higher X values reduce the damping capability of the power network system. Second, transferring a given amount of active power in a circuit that has a larger X value while maintaining unitary voltages causes the transfer angle δ to increase. Since

$$P = \frac{1}{X} sin δ ,$$

sin δ increases proportionally to the higher X value, and consequently cos δ decreases. That means that, when transferring a fixed amount of active power in the power network system with higher X values, the reactive power transfer is constrained to a lower amount,

$$Q = \frac{1}{X} ( 1 - cos δ ) .$$

As a result, the voltage is more severely impacted by a fault, not because of the change in voltage transient time constant but because the reactive power supply that can maintain the voltage is smaller, thus the voltage drops to a lower point. The above-mentioned root causes suggest higher values of X yields more severe frequency and voltage oscillations and, if sufficient reactive power headroom is not available when trying to sustain voltage during transients (a common drawback issue with GFL IBRs), the voltage drops are greater, as shown in FIG. 5C.

Finally, while the X/R ratio is widely used by power engineers to quantify grid strength, where X and R are the inductance and resistance of the lines, respectively, there is no reasonable grounds to consider the X/R ratio as a meaningful or effective means to quantify the grid strength in high voltage transmission networks, as illustrated in FIG. 6F. The X/R ratio may be effective in low voltage networks, e.g., microgrids or distribution networks, but as the voltage rating increases, the R value per mile becomes smaller while the changes in X value per mile are quite small (reactance changes with the logarithm of conductor radius). That is why in high voltage transmission networks, the ohmic losses are often neglected. Hence, in high voltage networks, the X/R ratio may not be considered.

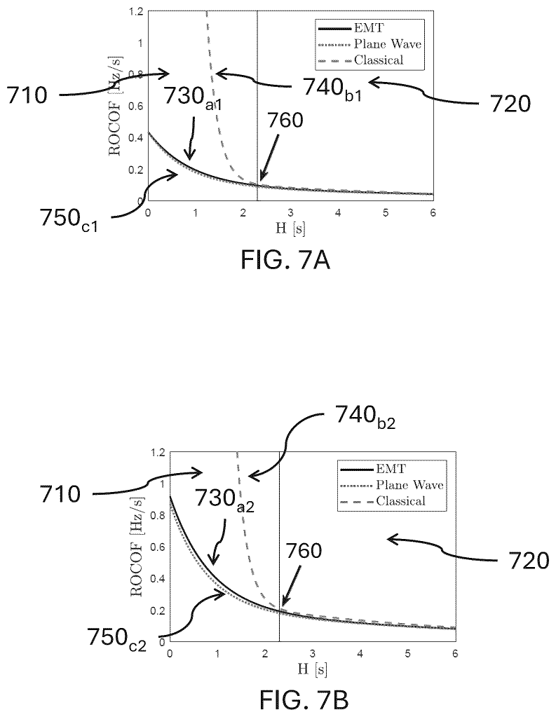

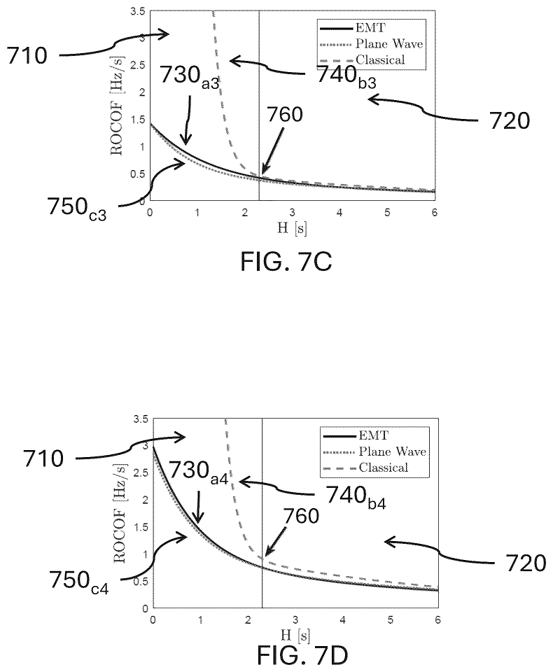

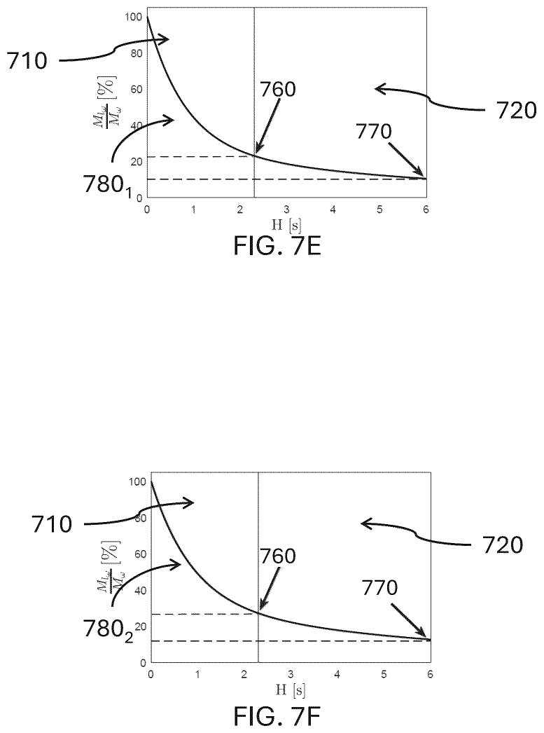

FIGS. 7A-7D illustrates data plots for assessing power system dynamics with and without electromagnetic momentum under various scenarios, which include the first scenario, in which a power network system includes three generators with nine nodes and 4.5 megawatts (MW) power output, the second scenario, in which a power network system includes three generators with nine nodes and 9 MW power output, the third scenario, in which a power network system includes a power network system includes 10 generators with 39 nodes and 307 MW power output, and the fourth scenario, in which a power network system includes 10 generators with 39 nodes and 615 MW power output. FIGS. 7A-7D show simulation results under the four scenarios, respectively.

The simulation results are obtained by increasing or decreasing the conventional power generators and the IBRs. For example, in left side of the low inertial region 710, the number of IBRs is three in the first and second scenarios and ten in the third and fourth scenarios. Toward the region close to the boundary between the low inertial region 710 and the high inertial region 720, the number of IBRs is decreased to two in the first and second scenarios and to five in the third and fourth scenarios, and the number of conventional power generators are increased from zero to one in the first and second scenarios and to five in the third and fourth scenarios. After passing the boundary and in the right side of the high inertial region 720, the number of IBRs is decreased to zero in the four scenarios, and the number of conventional power generators are increased to three in the first and second scenarios and to ten in the third and fourth scenarios. These data points are interpolated to smooth the data plots 730-750.

It is noted that alphabet subscription “a” to 730-750 indicates that the data plots are obtained from the ground truth or measurement data, alphabet subscription “b” to 730-750 indicates that the data plots are from the conventional monitoring method, which only considers the mechanical inertia of the turbine in the conventional power generators, and alphabet subscription “c” to 730-750 indicates that the data plots are from the plane wave model, in which the mechanical and electromagnetic inertias are considered. Numerical subscriptions “1”-“4” to 730-750 indicates that the data plots are obtained from the first to fourth scenarios, respectively.

The horizontal axes of FIGS. 7A-7D represent a homogenous generator inertia constant H in unit of second, and the vertical axes represent a rate of change of frequency (ROCOF) in unit of hertz (Hz) per second. The generator inertial constant indicate kinetic or electric energy stored in the generators. For example, the higher the generator inertial constant is the more kinetic energy is stored in the generator, thereby slowing responses to sudden changes. Conventional power generators generally has a heavy turbine and a higher generator inertial constant, and slower response time to the changes. On the other hand, the lower the generator inertial constant is the less electromagnetic energy is stored in the transmission line, thereby responding to the sudden changes fast. IBRs do not have heavy turbine, has the lower generator inertial constant, and is able to respond to the sudden changes fast.

Now referring back to FIGS. 7A and 7B, when the first and second power network systems have a high generator inertial constant or is in the high inertial region 720, the simulated data plots 740_{b1} and 740_{b2} from the conventional model follow the ground truth or measurement data plots 730ₐ₁ and 730ₐ₂ in the first and second scenarios, respectively. Further, the differences of the rate of change of frequency between them are small due to the slow response time in the conventional power generators. That means that, when there are more conventional power generators than IBRs, the conventional model generally works well in following the measurement data plots 730ₐ₁ and 730ₐ₂.

On the other hand, in the low inertial region 710 or when the first and second power network systems have a low inertial constant, the simulated data plots 740_{b1} and 740_{b2} from the conventional model deviate from the ground truth or measurement data plots 730ₐ₁ and 730ₐ₂ in the first and second scenarios, respectively. Further, the differences of the rate of change of frequency between them are larger due to the fast response time in the IBRs. That means that, when there are more IBRs than conventional power generators, the conventional model generally do not work well in following the measurement data plots 730ₐ₁ and 730ₐ₂.

In both the low inertial region 710 and the high inertial region 720, the simulated data plots 730ₐ₁ and 730ₐ₂ according to the plane wave model closely follow the ground truth or measurement data plots 730ₐ₁ and 730ₐ₂ under the first and second scenarios. In other words, in a configuration where the generator inertia constant H is equal to zero or all generators are IBRs, the electromagnetic momentum of the power lines in the power network system dynamics plays a great role in modeling the power network system.

In the third and fourth scenarios, similar patterns are shows in FIGS. 7C and 7D. Specifically, the simulated data plots 740_{b3} and 740_{b4} from the conventional model follow the ground truth or measurement data plots 730ₐ₃ and 730ₐ₄ in the high inertial region 720 but do not in the low inertial region. On the other hand, the simulated data plots 740_{c3} and 740_{c4} from the plane wave model follow the ground truth or measurement data plots 730ₐ₃ and 730ₐ₄ both in the high inertial region 720 and in the low inertial region 710.

In aspects, the frequency response of GFMs and subsequently their ROCOF is a function of their control value, specifically a droop value. For the case with the lowest inertia, the droop coefficient of 5% may be applied. In all GFM case, the response is expected from the GFMs within a few milliseconds of control delay, just long enough to measure the ROCOF as the frequency deviates momentarily before the control response comes into effect. It is noted that these simulations are done without any load inertia. Thus, all momenta in the power network systems are provided by the generators or the transmission lines.

A phase transition point 760 is shown in FIGS. 7A-7F and a baseline contribution 770 from the transmission lines is shown in FIGS. 7E and 7F. the phase transition point 760 is a point where the low and high inertial regions meet or where the mechanical momentum is at its critical value. When the mechanical momentum declines further from this value, the dominant dynamics of the power network system change in nature and their governance principles switch from the lows of electromechanical forces to the laws of electromagnetic forces. Subsequently, the power network systems enter the low inertial region 710 from the high inertial region 720.

FIGS. 7E and 7F illustrate data plots for assessing the ratio of electromagnetic momentum to overall momenta present in the first and second power networks, respectively. The horizontal axis represents a homogenous generator inertia constant H in unit of second, and the vertical axes represent a percent rate of the electromagnetic momentum to the total momenta in the power network systems. At the phase transition point 760, the contributions of the electromagnetic momentum compared to the total momentum in the first and second power network systems reach about 22.95% and about 27.1%, respectively. The percentages for the phase transition point 760 are provided as examples and may be greater or smaller than 22.95% and 27.1%.

Further, the baseline contribution 770 may suggest that the electromagnetic momentum contributes to the power network system about 10.2% in the first power network system and 12.6% in the second power network system. That means, even when there are only synchronous power resources in the power network systems, the electromagnetic momentum may still exert on the frequency behavior of the power network system. This emphasizes the application of the electromagnetic momentum when monitoring the frequency behavior regardless of the configuration of the power network systems.

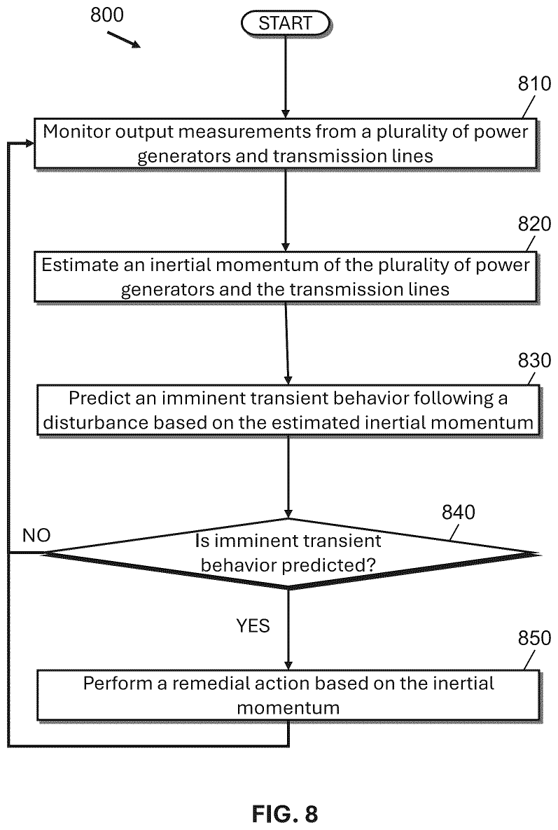

Referring to FIG. 8, illustrated is a flowchart for a method 800 for monitoring dynamic security in a power grid network system according to various aspects of the present disclosure. The method 800 may predict an imminent transient behavior following a blackout or short circuit based on an inertial momentum of the plurality of power generators. As IBRs have immerged into conventional legacy power generators, which are synchronous power resources, conventional monitoring models do not appreciate characteristics of low electric momenta of IBRs and electromagnetic momenta of the transmission lines. The method 800 utilizes an inertial momentum, which includes inertial momenta of synchronous power resources, electromagnetic momenta of the IBRs, and the electromagnetic momentum of the transmission lines. Thereby, an imminent transient behavior of a power generator following a disturbance may be predicted and corresponding remedial actions may be performed thereafter.

The method 800 may include step 810, which obtains output measurements from the plurality of power generators and the transmission lines connecting the plurality of power generators and loads. The output measurements may include voltage, current, phase, frequency, real power, reactive power, internal resistance, internal inductance, internal capacitance, and the likes. In an aspect, the reactive power may be obtained from the IBRs and not from the synchronous power resources. In another aspect, the reactive power may be also obtained from the synchronous power resources, as illustrated in FIGS. 7E and 7F. In still another aspect, values of turbines in each synchronous power resource, which can be used to calculate or estimate the mechanical momentum of each synchronous power resource, may be obtained at step 810. In a still further aspect, the inertial momentum of the power network system may be estimated at any location, node, generator, transmission line, or load in the power network system.

Based on all outputs obtained from each power generator, the method 800 may include step 820, which is executed by estimating the inertial momentum of the plurality of power generators and the transmission lines. As described above, the inertial momentum includes a mechanical momentum of each synchronous power resource in the power network system, an electric momentum of each IBR in the power network system, and an electromagnetic momentum of the transmission lines. In an aspect, the inertial momentum may be estimated for each power generator in the power network system. Specifically, for a synchronous power resource, the inertial momentum may be mainly in form of the mechanical momentum, and for each IBR, the inertial momentum may be mainly in form of the electric momentum, and for the transmission lines, the inertial momentum may be mainly in form of the electromagnetic momentum. In another aspect, the inertial momentum at a node may be a sum of the mechanical momentum, the electric momentum, and the electromagnetic momentum. In still another aspect, the inertial momentum may be estimated between two generators, among any number of generators, or among one or more generators and one or more loads.

The method 800 may further include step 830, which is executed by predicting an imminent transient behavior following a disturbance based on the inertial momentum. At step 830, the inertial momentum may be monitored across the power network system, and any abrupt changes or abnormal patterns may be indicative of the disturbance, which may be present in imbalances between generation and load, transmission faults, and sudden loss of generation or load. For example, a sudden drop in the inertial momentum of a synchronous power resource leads to an immediate decline in the frequency. After the disturbance, the voltage and frequency of the voltage may drop or oscillate. By monitoring the inertial momentum, the imminent transient behavior such as drops or oscillation of voltage and frequency may be predicted.

In an aspect, a rate of change of frequency, as the imminent transient behavior may be predicted based on the inertial momentum. For example, the inertial momentum dampens the ROCOF during disturbances. A faster ROCOF may indicate lower inertial momentum and higher vulnerability of the power network system. Thus, based on the inertial momentum, behavior of the ROCOF may be predicted.

In another aspect, a phase angle difference may be predicted based on the inertial momentum at step 830. For example, significant deviations in the phase angle between nodes may suggest instability in power flows after disturbances. Thus, based on the inertial momentum, such deviations may be predicted.

In a further aspect, an oscillatory behavior may be predicted based on the inertial momentum following the disturbance at step 830. For example, based on the inertial momentum, presence of low-frequency oscillation, which indicates weakening stability of the power network system, may be predicted.

The method 800 may further include step 840, which is executed by determining whether the imminent transient behavior is predicted based on the inertial momentum at step 830. When it is determined that no imminent transient behavior is predicted at step 840, the method 800 may go back to step 810 and continue monitoring the power network system for predicting imminent transient behaviors following disturbances.

When it is determined that the imminent transient behavior is predicted at step 830, the method may further include step 850, which is executed by performing a remedial action based on the inertial momentum. The remedial action may include triggering mitigation actions, such as UFLS, so as to prevent cascading failures, or performing the frequency droop control, which adjusts the output of the generators based on frequency deviation using droop characteristics. The output of generators may include voltage, frequency, currency, and frequency. The list of remedial actions is not limited to these but may include any other remedial actions to the generator side, to the load side, or to the transmission line side, as readily appreciated by persons having skilled in the power generation area.

In aspects, the method 800 or any other control modules may be performed by a computing device, server, tablet, or cloud server or implemented by one or modules or programs executed by one or more computing systems. Interconnection of computing systems may be facilitated distributed computing systems, such as so-called “cloud” computing systems. In this description, “cloud computing” may be systems or resources for enabling ubiquitous, convenient, on-demand network access to a shared pool of configurable computing resources (e.g., networks, servers, storage, applications, services, etc.) that can be provisioned and released with reduced management effort or service provider interaction. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Cloud and remote based service applications are prevalent. Such applications are hosted on public and private remote systems such as clouds and usually offer a plurality of web based services for communicating back and forth with clients.

Many computers are intended to be used by direct user interaction with the computer. As such, computers have input hardware and software user interfaces to facilitate user interaction. For example, a modem general-purpose computer may include a keyboard, mouse, touchpad, camera, etc. for allowing a user to input data into the computer. In addition, various software user interfaces may be available.

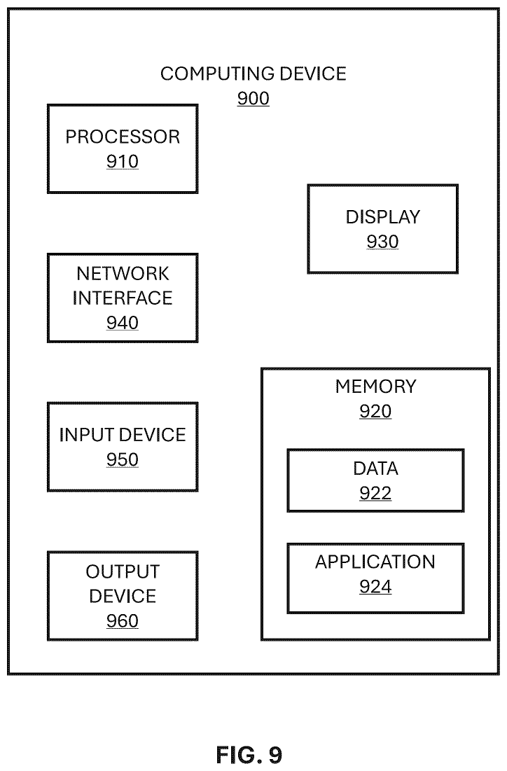

Turning now to FIG. 9, disclosed aspects may comprise or utilize a special purpose or general-purpose computing device 900 including computer hardware, as discussed in greater detail below. The computing device 900 may be a laptop or desktop computer, server, edge computer, or cloud computer, which can perform any functions, methods, processes disclosed above. The computing device 900 may include a processor 910, a memory 920, a display 930, a network interface 940, an input device 950, and/or an output device 960. The memory 920 includes any non-transitory computer-readable storage media for storing data and/or software that is executable by the processor 910 and which controls the operation of the computing device 900.

The computing device 900 may include an operating system configured to perform executable instructions. The operating system is, for example, software, including programs and data, which manages hardware of the disclosed apparatus and provides services for execution of applications for use with the disclosed apparatus. Those of skill in the art will recognize that suitable operating systems include, by way of non-limiting examples, FreeBSD®, OpenBSD, NetBSD®, Linux®, Unix®, Apple® Mac OS X Server®, Oracle® Solaris®, Windows Server®, Windows®, Novell®, NetWare®, iOS®, Android®, or any other operating system readily available. In some aspects, the operating system is provided by cloud computing.

The processor 910 may be a general purpose processor, a specialized graphics processing unit (GPU) configured to perform specific graphics processing tasks (e.g., parallel processing for training and testing data packets for potential cyberattacks) while freeing up the general-purpose processor to perform other tasks, and/or any number or combination of such processors, digital signal processors (DSPs), general purpose microprocessors, application specific integrated circuits (ASICs), field programmable logic arrays (FPGAs), or other equivalent integrated or discrete logic circuitry. Accordingly, the term “processor” as used herein may refer to any of the foregoing structure or any other physical structure suitable for implementation of the described techniques. Also, the techniques could be fully implemented in one or more circuits or logic elements.

The memory 920 may include one or more solid-state storage devices such as flash memory chips. Alternatively or in addition to the one or more solid-state storage devices, the memory 920 may include one or more mass storage devices connected to the processor 910 through a mass storage controller (not shown) and a communications bus (not shown). Although the description of computer-readable media contained herein refers to a solid-state storage, it should be appreciated by those skilled in the art that computer-readable storage media can be any available media that can be accessed by the processor 910. That is, computer readable storage media may include non-transitory, volatile and non-volatile, removable and non-removable media implemented in any method or technology for storage of information such as computer-readable instructions, data structures, program modules or other data. For example, computer-readable storage media includes random access memory (RAM), read-only memory (ROM), erasable programmable read-only memory (EPROM), electrically erasable programmable read-only memory (EEPROM), flash memory or other solid state memory technology, compact disc read-only memory (CD-ROM), digital video disc (DVD), Blu-Ray or other optical storage, magnetic cassettes, magnetic tape, magnetic disk storage or other magnetic storage devices, or any other medium which can be used to store the desired information and which can be accessed by the computing device 900.

The memory 920 may store application 924 (e.g., fingerprint database, Al algorithm, etc.) and/or data 922 (e.g., fingerprints). The application 924 may, when executed by processor 910, cause the display 930 to present the user interface to provide information to users. The application 924 may be one or more software programs stored in the memory 920 and executed by the processor 910 of the computing device 900. The application 924 may be installed directly on the computing device 900 or via the network interface 940. The application 924 may run natively on the computing device 900, as a web-based application, or any other format known to those skilled in the art.

In an aspect, the application 924 may include a sequence of process-executable instructions, which can perform any of the herein described methods, programs, algorithms or codes, which are converted to, or expressed in, a programming language or computer program. The terms “programming language” and “computer program,” as used herein, each include any language used to specify instructions to a computer, and include (but is not limited to) the following languages and their derivatives: Assembler, Basic, Batch files, BCPL, C, C+, C++, C, Delphi, Fortran, Java, JavaScript, python, machine code, operating system command languages, Pascal, Perl, PL1, scripting languages, Visual Basic, meta-languages which themselves specify programs, and all first, second, third, fourth, fifth, or further generation computer languages. Also included are database and other data schemas, and any other meta-languages. No distinction is made between languages which are interpreted, compiled, or use both compiled and interpreted approaches. No distinction is made between compiled and source versions of a program. Thus, reference to a program, where the programming language could exist in more than one state (such as source, compiled, object, or linked) is a reference to any and all such states. Reference to a program may encompass the actual instructions and/or the intent of those instructions.

The display 930 may be a cathode ray tube (CRT), a liquid crystal display (LCD), a thin film transistor liquid crystal display (TFT-LCD), and an organic light emitting diode (OLED) display. In certain aspects, the OLED display is a passive-matrix OLED (PMOLED) or active-matrix OLED (AMOLED) display. In aspects, the display 930 is a plasma display, and a video projector. In various aspects, the display 930 may be interactive (e.g., having a touch screen or a sensor such as a camera, a 3D sensor, etc.) that can detect user interactions/gestures/responses and the like so as to serve as both an input and output device.

The network interface 940 may be configured to connect to a network such as a local area network (LAN) consisting of a wired network and/or a wireless network, a wide area network (WAN), a wireless mobile network, a Bluetooth network, and/or the internet.

For example, the computing device 900 may process digital measurement data obtained from the multi-arm spiral antenna, through the network interface 940, to identify a direction of the transmission source of the signal. The computing device 900 may update the Al algorithm, for example, the application 924, via the network interface 940. The computing device 900 may also display processed results and any notification from training and/or testing on the display 930.

The input device 950 may be any device by means of which a user may interact with the computing device 900, such as, for example, a mouse, keyboard, touch screen, and/or any other interface. The output device 960 may include any connectivity port or bus, such as, for example, parallel ports, serial ports, universal serial busses (USB), or any other similar connectivity port known to those skilled in the art.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmissions media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, and the like. The invention may also be practiced in distributed system environments where local and remote computer systems, which are linked (either by hardwired data links, wireless data links, or by a combination of hardwired and wireless data links) through a network, both perform tasks. In a distributed system environment, program modules may be located in both local and remote memory storage devices.

Alternatively, or in addition, the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

Computing system functionality can be enhanced by a computing system for ability to be interconnected to other computing systems and power generators via network connections. Network connections may include, but are not limited to, connections via wired or wireless Ethernet, cellular connections, or even computer to computer connections through serial, parallel, USB, or other connections. The connections allow a computing system to access services at other computing systems and to quickly and efficiently receive application data from other computing systems.

Examples of software user interfaces include graphical user interfaces, text command line based user interface, function key or hot key user interfaces, and the like.

### Example Implementations

In view of the foregoing, the present disclosure relates, for example and without being limited thereto, to the following aspects:

According to the first aspect, a power grid monitoring system includes one or more processors and a memory including instructions. The instructions, when executed by the one or more processors, cause the power grid monitoring system to monitor output measurements from a plurality of power generators and transmission lines connecting the plurality of power generators and loads, estimate an inertial momentum of the plurality of power generators, and predict an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

According to the second aspect claimed in the first aspect, the plurality of power generators includes synchronous power resources, inverter-based generators, or both.

According to the third aspect claimed in any previous aspects, an inertial momentum of each synchronous power resource is estimated based on an angular velocity and a mass of a turbine thereof.

According to the fourth aspect claimed in any previous aspects, an electric momentum of each inverter-based generator is estimated based on a momentum of frequency and a momentum of voltage thereof.

According to the fifth aspect claimed in any previous aspects, the inertial momentum is used to adjust a voltage, a current, and an alternating current frequency of synchronous power resources.

According to the sixth aspect claimed in any previous aspects, when the imminent transient behavior is predicted, the instructions, when executed by the one or more processors, further cause the power grid monitoring system to perform a remedial action.

According to the seventh aspect claimed in any previous aspects, the electromagnetic momentum is further based on characteristics, a voltage rating, and a length of the transmission line.

According to the eighth aspect claimed in any previous aspects, the electromagnetic momentum is based on a power transfer of the transmission line, both active and reactive.

According to the nineth aspect claimed in any previous aspects, the electric momentum is used to adjust a voltage, a current, and an alternating current frequency of inverter-based generators.

According to the tenth aspect claimed in any previous aspects, the inverter-based generators include one or more grid-following inverter-based generators or one or more grid-forming inverter-based generators.

According to the eleventh aspect, a method for monitoring a plurality of power generators includes monitoring output measurements from a plurality of power generators, estimating an inertial momentum of the plurality of power generators and transmission lines connecting the plurality of power generators and loads, and predicting an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

According to the twelfth aspect claimed in the eleventh aspect, the plurality of power generators includes synchronous power resources, inverter-based generators, or both.

According to the thirteenths claims in any previous aspects from the eleventh aspect, an inertial momentum of each synchronous power resource is estimated based on an angular velocity and a mass of a turbine thereof.

According to the fourteenth aspect claimed in any previous aspects from the eleventh aspect, an electric momentum of each inverter-based generator is estimated based on a control apparatus and filter components thereof.

According to the fifteenth aspect claimed in any previous aspects from the eleventh aspect, the inertial momentum is used to adjust a voltage, a current, and an alternating current frequency of synchronous power resources.

According to the sixteenth aspect claimed in any previous aspects from the eleventh aspect, when the imminent transient behavior is predicted, the instructions, when executed by the one or more processors, further cause the power grid monitoring system to perform a remedial action.

According to the seventeenth aspect claimed in any previous aspects from the eleventh aspect, the electromagnetic momentum is further based on characteristics, a voltage rating, and a length of the transmission line.

According to the eighteenth aspect claimed in any previous aspects from the eleventh aspect, the electric momentum is used to adjust a voltage, a current, and an alternating current frequency of inverter-based generators.

According to the nineteenth aspect claimed in any previous aspects from the eleventh aspect, the inverter-based generators include one or more grid-following inverter-based generators or one or more grid-forming inverter-based generators.

According to the twentieth aspect, a nontransitory storage medium includes instructions stored thereon that, when executed by a computer, cause the computer to perform a method for monitoring a plurality of power generators. The method includes monitoring output measurements from a plurality of power generators, estimating an inertial momentum of the plurality of power generators and transmission lines connecting the plurality of power generators and loads, and predicting an imminent transient behavior following a disturbance in at least one of the plurality of power generators, the transmission lines, or the loads based on the inertial momentum. The inertial momentum is based on an electromagnetic momentum in the transmission lines and mechanical and electrical momenta of the plurality of the power generators.

The present disclosed may be embodied in other specific forms without departing from its spirit or characteristics. The described aspects are to be considered in all respects only as illustrative and not restrictive. The scope of the disclosure is, therefore, indicated by the appended claims rather than by the foregoing description. All changes which come within the meaning and range of equivalency of the claims are to be embraced within their scope.

What is claimed is:

1. A power grid monitoring system, comprising:
one or more processors; and
a memory including instructions that, when executed by the one or more processors, cause the power grid monitoring system to:
monitor output measurements from a plurality of power generators and transmission lines connecting the plurality of power generators and loads;
estimate an inertial momentum of the plurality of power generators and the transmission lines; and
predict an imminent transient behavior following a disturbance in at least one of the plurality of power generators, the transmission lines, or the loads based on the inertial momentum,
wherein the inertial momentum is based on an electromagnetic momentum in the transmission lines and mechanical and electrical momenta of the plurality of the power generators.

2. The power grid monitoring system according to claim 1, wherein the plurality of power generators includes synchronous power resources, inverter-based generators, or both.

3. The power grid monitoring system according to claim 2, wherein an inertial momentum of each synchronous power resource is estimated based on an angular velocity and a mass of a turbine thereof.

4. The power grid monitoring system according to claim 2, wherein an electric momentum of each inverter-based generator is estimated based on a momentum of frequency and a momentum of voltage thereof.

5. The power grid monitoring system according to claim 4, wherein the inertial momentum is used to adjust a voltage, a current, and an alternating current frequency of synchronous power resources.

6. The power grid monitoring system according to claim 1, wherein, when the imminent transient behavior is predicted, the instructions, when executed by the one or more processors, further cause the power grid monitoring system to perform a remedial action.

7. The power grid monitoring system according to claim 1, wherein the electromagnetic momentum is further based on characteristics, a voltage rating, and a length of the transmission line.

8. The power grid monitoring system according to claim 1, wherein the electromagnetic momentum is based on a power transfer of the transmission line, both active and reactive.

9. The power grid monitoring system according to claim 1, wherein the electric momentum is used to adjust a voltage, a current, and an alternating current frequency of inverter-based generators.

10. The power grid monitoring system according to claim 2, wherein the inverter-based generators include one or more grid-following inverter-based generators or one or more grid-forming inverter-based generators.

11. A method for monitoring a plurality of power generators, the method comprising:
monitoring output measurements from a plurality of power generators;
estimating an inertial momentum of the plurality of power generators and transmission lines connecting the plurality of power generators and loads; and
predicting an imminent transient behavior following a disturbance in at least one of the plurality of power generators, the transmission lines, or the loads based on the inertial momentum, wherein the inertial momentum is based on an electromagnetic momentum in the transmission lines and mechanical and electrical momenta of the plurality of the power generators.

12. The method according to claim 11, wherein the plurality of power generators includes synchronous power resources, inverter-based generators, or both.

13. The method according to claim 12, wherein an inertial momentum of each synchronous power resource is estimated based on an angular velocity and a mass of a turbine thereof.

14. The method according to claim 12, wherein an electric momentum of each inverter-based generator is estimated based on a control apparatus and filter components thereof.

15. The method according to claim 14, wherein the inertial momentum is used to adjust a voltage, a current, and an alternating current frequency of synchronous power resources.

16. The method according to claim 11, wherein, when the imminent transient behavior is predicted, the instructions, when executed by the one or more processors, further cause the power grid monitoring system to perform a remedial action.

17. The method according to claim 11, wherein the electromagnetic momentum is further based on characteristics, a voltage rating, and a length of the transmission line.

18. The method according to claim 11, wherein the electric momentum is used to adjust a voltage, a current, and an alternating current frequency of inverter-based generators.

19. The method according to claim 11, wherein the inverter-based generators include one or more grid-following inverter-based generators or one or more grid-forming inverter-based generators.

20. A nontransitory storage medium including instructions stored thereon that, when executed by a computer, cause the computer to perform a method for monitoring a plurality of power generators, the method comprising:
monitoring output measurements from a plurality of power generators;
estimating an inertial momentum of the plurality of power generators and transmission lines connecting the plurality of power generators and loads; and
predicting an imminent transient behavior following a disturbance in at least one of the plurality of power generators, the transmission lines, or the loads based on the inertial momentum,
wherein the inertial momentum is based on an electromagnetic momentum in the transmission lines and mechanical and electrical momenta of the plurality of the power generators.
